(19) United States
(12) Patent Application Publication
(10) Pub. No.: US 2008/0227257 A1
(43) Pub. Date: Sep. 18, 2008

(54) METHODS FOR FORMING SEMICONDUCTOR DEVICES

(75) Inventor: Ming-Teng Hsieh, Taoyuan (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/856,514

(22) Filed: Sep. 17, 2007

(30) Foreign Application Priority Data
Mar. 12, 2007 (TW) TW96108410

(51) Int. Cl. H01L 21/336

(52) U.S. Cl. 438/300; 257/E21.409

(57) ABSTRACT

A method for forming a semiconductor device comprises providing a substrate. A N type region and a non-N type region are formed in the substrate. The substrate is wet etched to form a protruding portion in the N type region and a concave portion in the non-N type region. A gate structure is formed in the concave portion and insulating spacers are formed on sidewalls of the protruding portion.

### BACKGROUND OF THE INVENTION

1. Field of the Invention

The present invention relates to semiconductor devices and methods for forming the same, and in particular relates to memory devices and methods for forming the same.

2. Description of the Related Art

For the rapidly evolving integrated circuit industry, the development trends are higher performance, miniaturization, and higher operating speed. Shrinking circuit dimensions is particularly important in dynamic random access memory (DRAM) fabrication. Most DRAMs, used as a memory device, with capacity exceeding 512 to 1000 MB, comprise transistors and capacitors. Greater integration is thus required for a higher-capacity and higher-speed DRAMs as size decreases.

FIG. 1 is a cross-section of a conventional memory device. Typically, a memory device comprises a memory array region and a peripheral circuit region. For brevity, only the memory array region is illustrated below. Metal oxide semiconductor (MOS) transistors are disposed in the memory array region. Each MOS transistor comprises a gate dielectric layer 12, a gate conductive layer 13, gate spacers 15, a gate capping layer 14 and source/drain regions 16 in a substrate 10 neighboring the gate conductive layer 13. An interlayer-dielectric (ILD) layer 18 is deposited on the substrate 10. A bit line contact 19 is formed in the ILD layer 18 to electrically contact the source/drain regions 16.

As size of the semiconductor device is reduced for higher operating speed and higher packaging density, a channel length “Lg” of the MOS transistor must also shrink. In addition, dimensions of other elements must also be reduced to maintain electrical property of the semiconductor device. For example, a depth “d” of the source/drain regions 16 reduces along with the channel length “Lg”. Typically, a shallow implant process is applied to form a shallow junction when size of the DRAM decreases. A low energy ion beam is projected to a target wafer during the shallow implant process, thus allowing a shallow doped region to be formed on the target wafer. However, it is difficult to control dimensions and focus of an ion beam to a target wafer during low energy ion beam implantation. Namely, doping concentration and range is out of control when utilizing low energy shallow implantation processes.

### BRIEF SUMMARY OF THE INVENTION

A detailed description is given in the following embodiments with reference to the accompanying drawings.

In accordance with an embodiment of the invention, a method for forming a semiconductor device is provided. The method comprises providing a substrate. A N type region and a non-N type region are formed in the substrate. The substrate is wet etched to form a protruding portion in the N type region and a concave portion in the non-N type region. A gate structure is formed in the concave portion and insulating spacers are formed on sidewalls of the protruding portion.

In accordance with another embodiment of the invention, a method for forming a semiconductor device is provided. The method comprises providing a substrate having a gate structure predetermined region and a source/drain predetermined region. N type dopants are doped in the substrate of the source/drain predetermined region. The substrate is wet etched to form a protruding portion corresponding to the source/drain predetermined region and a concave portion corresponding to the gate structure predetermined region. A gate structure is formed in the concave portion.

### BRIEF DESCRIPTION OF THE DRAWINGS

The present invention can be more fully understood by reading the subsequent detailed description and examples with references made to the accompanying drawings, wherein:

FIG. 1 is a cross-section of a conventional memory device; and

FIGS. 2 to 17 are schematic views showing methods for forming semiconductor devices according to embodiments of the invention.

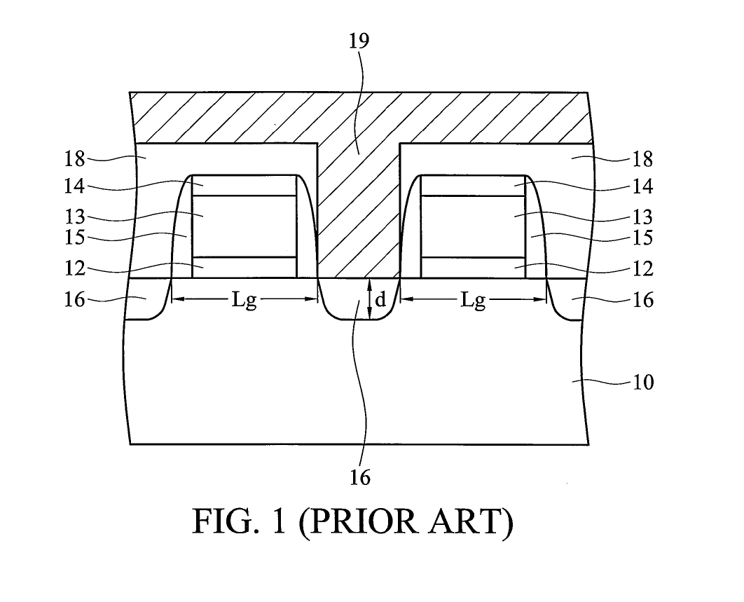

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

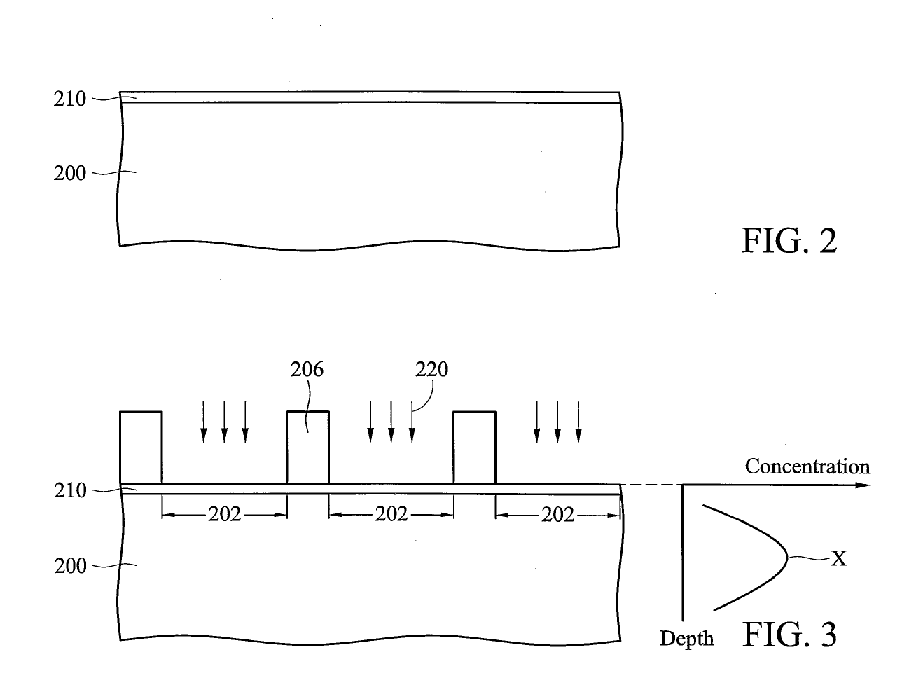

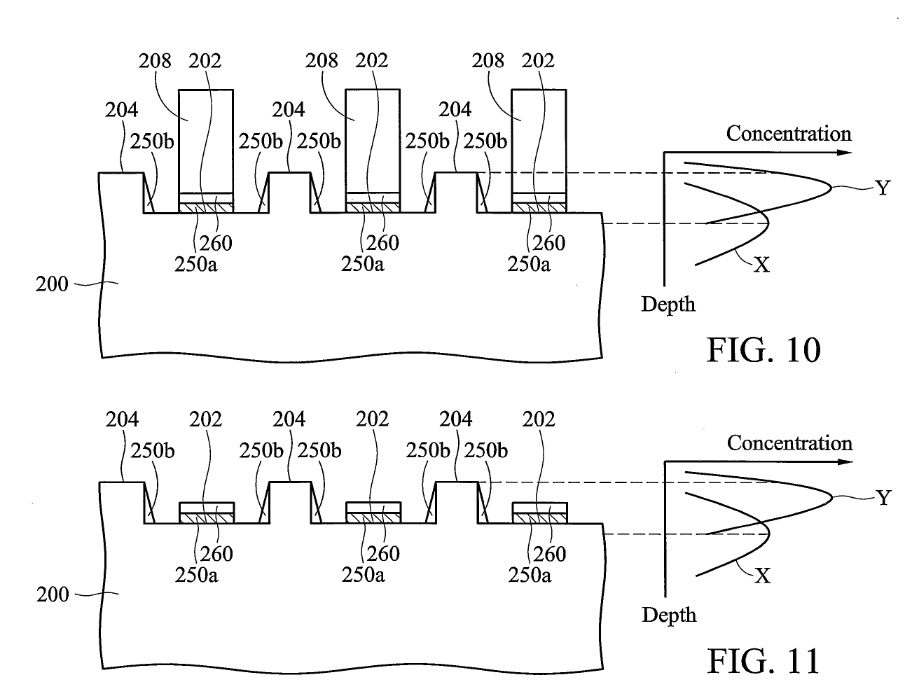

FIGS. 2 to 17 are schematic views showing methods for forming semiconductor devices according to embodiments of the invention. Referring to FIG. 2, a semiconductor substrate 200 which may comprise a doped or undoped silicon wafer is first provided. For example, the semiconductor substrate 200 may comprise a p-type or n-type silicon substrate. The semiconductor substrate 200 may comprise a memory array region and a peripheral circuit region. For brevity, only the memory array region is illustrated below. A sacrificial oxide layer 210 is next formed on the semiconductor substrate 200. The sacrificial oxide layer 210, is used to protect the semiconductor substrate 200 during the later ion implantation process, may comprise silicon oxide.

Referring to FIG. 3, a first patterned photo resist layer 206 is then formed on the sacrificial oxide layer 210 on the semiconductor substrate 200 by using a photolithography process. The first patterned photo resist layer 206 defines gate structure predetermined regions 202. A first ion implantation 220 is performed to dope p-type dopants, such as boron, in the gate structure predetermined regions 202 of the semiconductor substrate 200 by using the first patterned photo resist layer 206 as a mask. For example, doping concentrate and depth distribution X made by the first ion implantation 220 may be as FIG. 3 shows. After the first ion implantation 220 is finished, the first patterned photo resist layer 206 is removed by plasma ashing or wet striping.

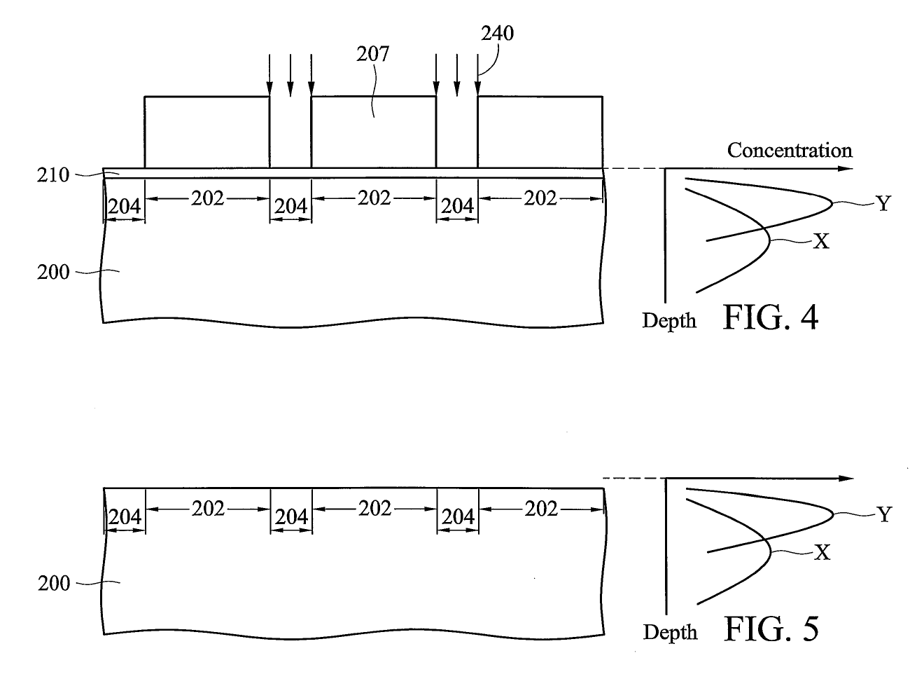

Referring to FIG. 4, a second patterned photo resist layer 207 in next formed on the sacrificial oxide layer 210 on the semiconductor substrate 200 by using a photolithography process. The second patterned photo resist layer 207 defines source/drain predetermined regions 204. A second ion implantation 240 is performed to dope n-type dopants, such as phosphorus, in the source/drain predetermined regions 204 of the semiconductor substrate 200 by using the second patterned photo resist layer 207 as a mask. For example, doping concentrate and depth distribution Y made by the second ion implantation 240 may be as FIG. 4 shows. After the second ion implantation 240 is finished, the second patterned photo resist layer 207 is removed by plasma ashing or wet striping.

Referring to FIG. 5, the sacrificial oxide layer 210 on the semiconductor substrate 200 may be removed by using buffer HF as an etchant. As described above, the gate structure predetermined region 202 of the semiconductor substrate 200 is a non-n type region such as a p-type region doped with boron, while the source/drain predetermined region 204 of the semiconductor substrate 200 may be a n-type region doped with phosphorus.

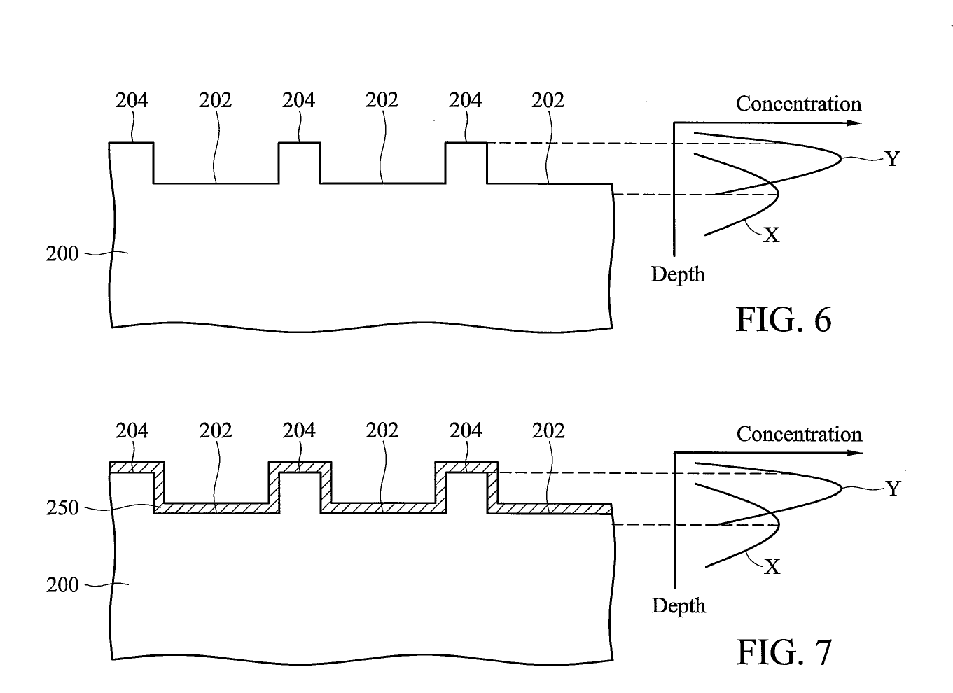

Referring to FIG. 6, a wet etching process may be performed to the semiconductor substrate 200. For example, the semiconductor substrate 200 such as silicon wafer may be etched by using KOH, tetramethyl ammonium hydroxide (TMAH) or ethylene diamine pyrochatechol (EDP) as an etchant. Because the etching rate of the semiconductor substrate 200 doped with phosphorus is less than the etching rate of the semiconductor substrate 200 undoped with phosphorus, the semiconductor substrate 200 may comprise a protruding portion corresponding to the source/drain predetermined region 204 and a concave portion corresponding to the gate structure predetermined region 202.

Referring to the FIG. 7, a gate dielectric layer 250 is formed on the semiconductor substrate 200. The gate dielectric layer 250 may comprise silicon oxide formed by thermal oxidation. Alternatively, the gate dielectric layer 250 may comprise silicon oxide, silicon nitride or silicon oxynitride formed by chemical vapor deposition (CVD).

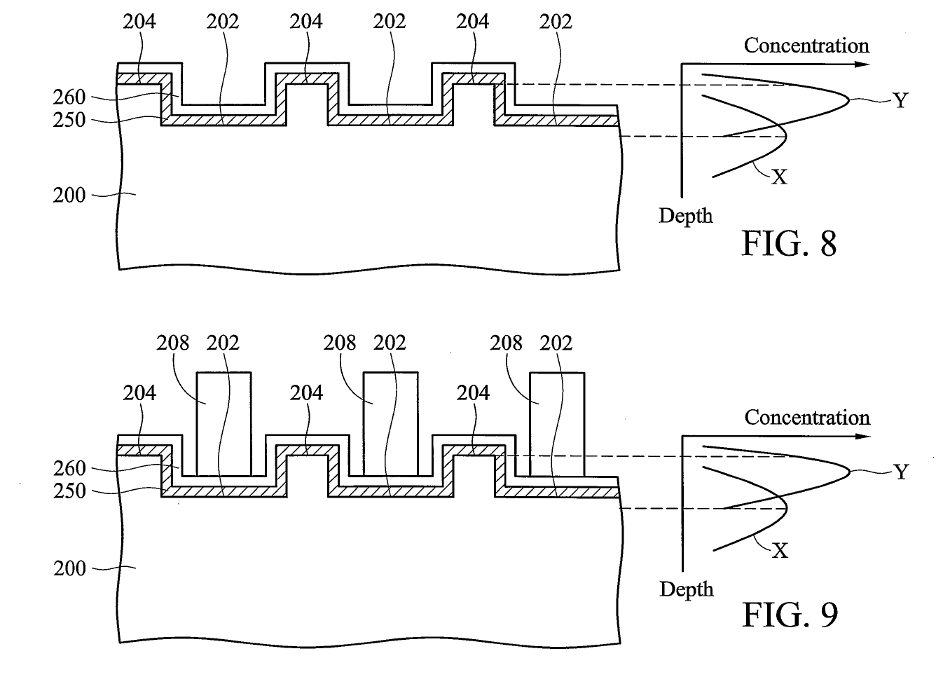

Referring to FIG. 8, a gate conductive layer 260 is formed on the gate dielectric layer 250. The gate conductive layer 260 may comprise conductive material such as polysilicon formed by CVD or metal formed by physical vapor deposition (PVD). Alternatively, the gate conductive layer 260 may comprise a stacked layer of polysilicon and tungsten silicon or a stacked layer of polysilicon, titanium and tungsten.

Referring to FIG. 9, a third patterned photo resist layer 208 is formed on the gate conductive layer 260 by using a photolithography process. Next, referring to FIGS. 9 to 11, the gate dielectric layer 250 and the gate conductive layer 260 is anisotropically etched by a dry etching process such as high density plasma etching or reactive ion etching and by using the third patterned photo resist layer 208 as a mask. Thus, a portion of the gate dielectric layer 250a and the gate conductive layer 260 is left on the gate structure predetermined region 202 and a portion of the gate dielectric layer 250 is left on sidewalls of the protruding portion, also referred as sidewalls of the source/drain predetermined region 204, to use as dielectric spacers 250b. The third patterned photo resist layer 208 is removed by plasma ashing or wet striping, as FIG. 11 shows.

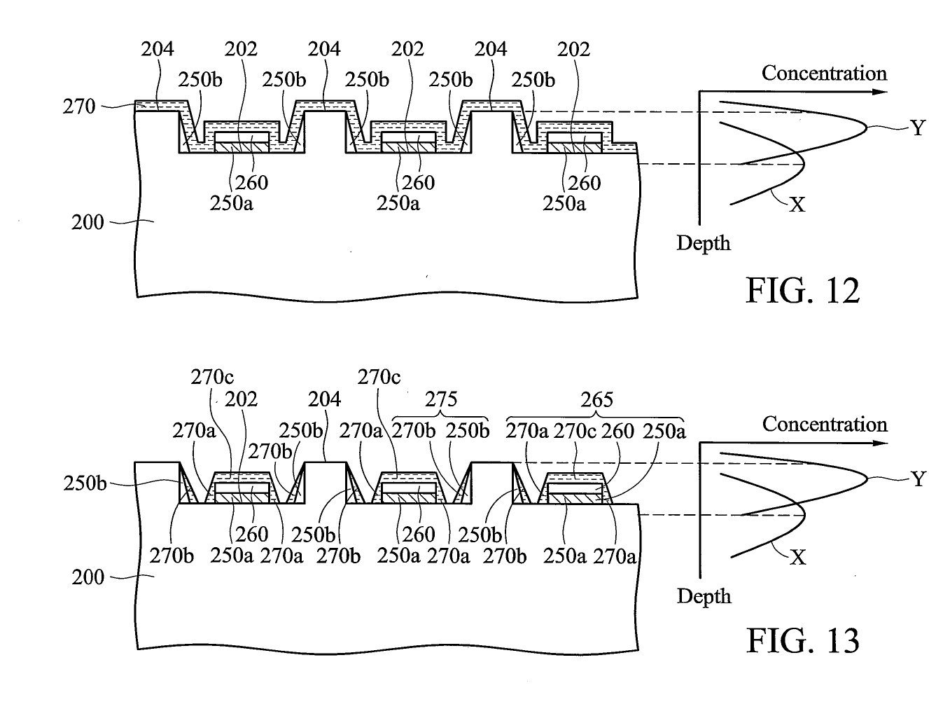

Referring to FIG. 12, a gate spacer material layer 270 is formed on the semiconductor substrate 200, the gate conductive layer 260, the gate dielectric layer 250a and the dielectric spacers 250b. The gate spacer material layer 270 may comprise silicon oxide or silicon nitride formed by low pressure chemical vapor deposition (LPCVD) or sub-atmospheric chemical vapor deposition (SACVD).

Referring to FIG. 13, the gate spacer material layer 270 is etched back by a dry etching process such as high density plasma etching or reactive ion etching to form gate spacers 270a on sidewalls of the gate conductive layer 260 and the gate dielectric layer 250a. While a portion of the gate spacer material layer 270 is left on the sidewalls of the protruding portion, also referred to as sidewalls of the source/drain predetermined region 204, to be utilized as dielectric spacers 270b. Preferably, a portion of the gate spacer material layer 270 is left on top of the gate conductive layer 260 to be utilized as gate capping layer 270c. The gate dielectric layer 250a, the gate conductive layer 260, the gate spacers 270a and the gate capping layer 270c in the gate structure predetermined region 202 form gate structure 265 while the dielectric spacers 250b and 270b on the sidewalls of the protruding portion (the source/drain predetermined region 204) form source/drain spacers 275.

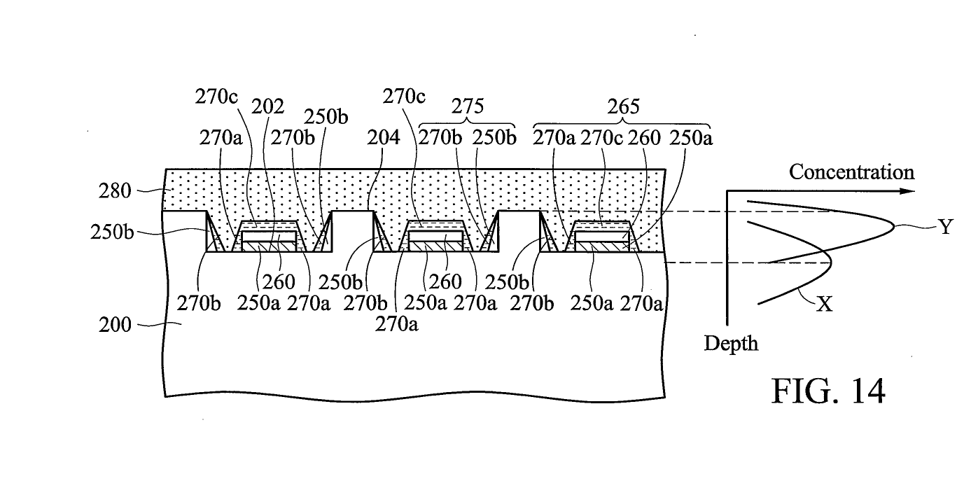

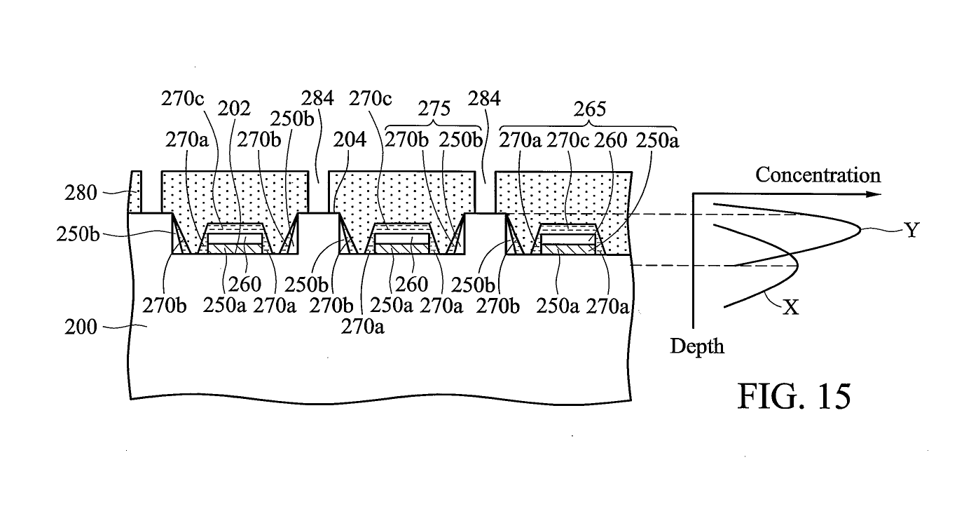

Referring to FIG. 14, a first interlayer dielectric layer 280 is blanketly formed on the semiconductor substrate 200. The first interlayer dielectric layer 280 may comprise BPSG, silicon oxide or other low dielectric constant material such as polyimide, diamond-like carbon, FSG or poly flrorinate carbon. After the first interlayer dielectric layer 280 is formed, a planarization process such as chemical mechanical polishing (CMP) or re-flow may be performed to planarize the first interlayer dielectric layer 280. Referring to FIG. 15, the first interlayer dielectric layer 280 is then patterned to form a bit line contact hole 284 exposing the source/drain predetermined region 204 by photolithography and etching processes.

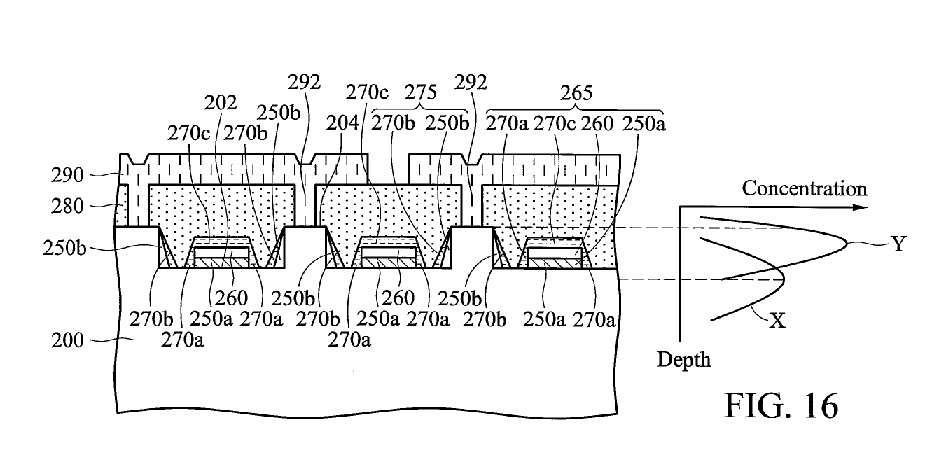

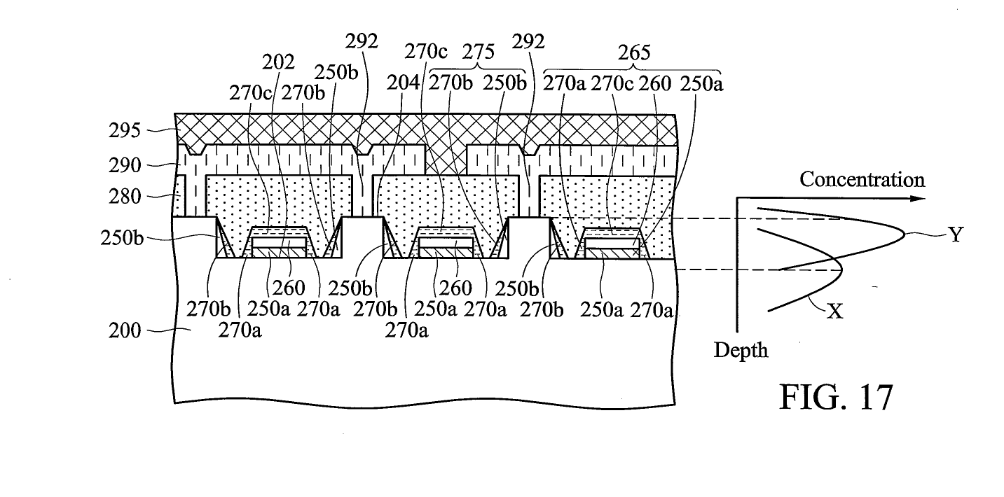

Referring to FIG. 16, conductive material such as Cu, W or Al is formed on the first interlayer dielectric layer 280 and filled into the bit line contact hole 284. A planarization process such as CMP may next be performed. Afterward, a bit line 290 and a bit line contact plug 292 are respectively formed on and in the first interlayer dielectric layer 280. A second interlayer dielectric layer 295 is then formed on the bit line 290, as FIG. 17 shows. The formation and material of the second interlayer dielectric layer 295 and the first interlayer dielectric layer 280 may be the same or different.

According to above embodiments, the semiconductor substrate 200 under the gate dielectric layer 250a in the gate structure predetermined 202 has relatively high p-type dopant concentration while the semiconductor substrate 200 neighboring the bit line contact plug 292 in the source/drain predetermined region has relatively high n-type dopant concentration. Therefore, by applying the above embodiments, a high doping concentration region can be formed near the surface of the semiconductor substrate 200 without using shallow implant. Furthermore, doping concentration and range is easy to control by using the above embodiments.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the Art). Therefore, the scope of the appended claims should be accorded the broadest interpretation so as to encompass all such modifications and similar arrangements.

What is claimed is:

1. A method for forming a semiconductor device, comprising
providing a substrate;
forming a N type region and a non-N type region in the substrate;
wet etching the substrate to form a protruding portion in the N type region and a concave portion in the non-N type region; and
forming a gate structure in the concave portion and insulating spacers on sidewalls of the protruding portion.

2. The method for forming a semiconductor device as claimed in claim 1, wherein the non-N type region comprises P type dopant.

3. The method for forming a semiconductor device as claimed in claim 1, as claimed in claim 1, wherein the substrate comprises silicon.

4. The method for forming a semiconductor device as claimed in claim 1, wherein wet etching the substrate comprises using KOH, TMAH or EDP as an etchant.

5. The method for forming a semiconductor device as claimed in claim 1, wherein the protruding portion is a source/drain region and the source/drain region is electrically connected to a bit line contact plug.

6. The method for forming a semiconductor device as claimed in claim 1, wherein forming the N type region in the substrate comprises performing an ion implantation.

7. The method for forming a semiconductor device as claimed in claim 6, further comprising forming a sacrificial oxide layer on the substrate before forming the N type region and the non-N type region in the substrate, wherein the sacrificial oxide layer is removed after the N type region and the non-N type region is formed.

8. The method for forming a semiconductor device as claimed in claim 1, wherein the gate structure comprises a gate dielectric layer, a gate conductive layer and gate spacers.

9. The method for forming a semiconductor device as claimed in claim 8, wherein forming the gate structure in the concave portion and the insulating spacers on the sidewalls of the protruding portion comprises:
forming a dielectric layer on the substrate;
forming a conductive layer on the dielectric layer;
patterning the dielectric layer and the conductive layer to form the gate dielectric layer and the gate conductive layer on the concave portion, wherein a portion of the dielectric layer remains on the sidewalls of the protruding portion;
forming a gate spacer material layer on the substrate, the gate dielectric layer and the gate conductive layer; and
etching back the gate spacer material layer to form the gate spacers on sidewalls of the gate dielectric layer and the gate conductive layer, wherein a portion of the gate spacer material layer remains on the sidewalls of the protruding portion;
wherein the dielectric layer and the gate spacer material layer remain on the sidewalls of the protruding portion forming the insulating spacers.

10. The method for forming a semiconductor device as claimed in claim 9, wherein a portion of the gate spacer material layer remains on a top surface of the gate conductive layer after etching back the gate spacer material layer.

11. The method for forming a semiconductor device as claimed in claim 5, wherein forming the bit line contact plug to electrically connect the source/drain region comprises:
forming an liter-layer dielectric layer on the substrate and the gate structure;
patterning the inter-layer dielectric layer to form a bit line contact hole exposing the protruding portion; and
forming a conductive material layer on the inter-layer dielectric layer and filling the bit line contact hole with the conductive material layer to form the bit line contact plug in the bit line contact hole.

12. A method for forming a semiconductor device, comprising
providing a substrate having a gate structure predetermined region and a source/drain predetermined region;
doping N type dopants in the substrate of the source/drain predetermined region;
wet etching the substrate to form a protruding portion corresponding to the source/drain predetermined region and a concave portion corresponding to the gate structure predetermined region;
forming a gate structure in the concave portion.

13. The method for forming a semiconductor device as claimed in claim 12, further comprising forming source/drain spacers on sidewalls of the protruding portion.

14. The method for forming a semiconductor device as claimed in claim 12, further comprising doping P type dopants in the substrate of the gate structure predetermined region.

15. The method for forming a semiconductor device as claimed in claim 12, wherein the substrate comprises silicon.

16. The method for forming a semiconductor device as claimed in claim 12, wet etching the substrate comprises using KOH, TMAH or EDP as an etchant.

17. The method for forming a semiconductor device as claimed in claim 12, further comprising forming a bit line contact plug to electrically connect the protruding portion.

18. The method for forming a semiconductor device as claimed in claim 12, wherein doping N type dopants in the substrate of the source/drain predetermined region comprising performing an ion implantation.

19. The method for forming a semiconductor device as claimed in claim 12, wherein the gate structure comprises a gate dielectric layer, a gate conductive layer and gate spacers.

20. The method for forming a semiconductor device as claimed in claim 13, wherein forming the source/drain spacers on the sidewalls of the protruding portion comprising:
forming a dielectric layer on the substrate;
forming a conductive layer on the dielectric layer;
patterning the dielectric layer and the conductive layer to form the gate dielectric layer and the gate conductive layer on the concave portion, wherein a portion of the dielectric layer remains on the sidewalls of the protruding portion;
forming a gate spacer material layer on the substrate, the gate dielectric layer and the gate conductive layer; and
etching back the gate spacer material layer to form the gate spacers on the sidewalls of the gate dielectric layer and the gate conductive layer in the concave portion, wherein a portion of the gate spacer material layer remains on the dielectric layer on the sidewalls of the protruding portion;
wherein the dielectric layer and the gate spacer material layer remain on the sidewalls of the protruding portion forming the insulating spacers.

21. The method for forming a semiconductor device as claimed in claim 20, wherein a portion of the gate spacer material layer remains on a top surface of the gate conductive layer in the concave portion after etching back the gate spacer material layer.

22. The method for forming a semiconductor device as claimed in claim 17, wherein forming the bit line contact plug to electrically connect the protruding portion comprises:
forming an inter-layer dielectric layer on the substrate and the gate structure;
patterning the inter-layer dielectric layer to form a bit line contact hole exposing the protruding portion; and
forming a conductive material layer on the inter-layer dielectric layer and filling the bit line contact hole with the conductive material layer to form the bit line contact plug in the bit line contact hole.
